(19) United States
(12) Patent Application Publication
(10) Pub. No.: US 2023/0203258 A1
(43) Pub. Date: Jun. 29, 2023

(54) FILMS FOR FLEXIBLE APPLICATIONS USING CELLULOSE NANOCRYSTALS (CNC) AND RESILIN-CBD

(71) Applicant: Smart Resilin Ltd., Karmey Yosef (IL)

(72) Inventors: Oded Shoseyov, S, AZ (US); Liron Nesiel, Rehovot (IL); Amir Rudich, Rehovot (IL); Daniel Voignac, Tel Aviv (IL)

(73) Assignees: Smart Resilin Ltd., Karmey Yosef (IL); YISSUM RESEARCH DEVELOPMENT COMPANY OF THE HEBREW UNIVERSITY OF JERUSALEM LT, Jerusalem (IL)

(21) Appl. No.: 17/999,398

(22) PCT Filed: May 19, 2021
(86) PCT No.: PCT/IB2021/054318

§ 371 Date: Nov. 20, 2022

Related U.S. Application Data
(60) Provisional application No. 63/026,797, filed on May 19, 2020.

(51) Int. Cl. C08J 5/18

(52) U.S. Cl. CPC C08J 5/18; C08J 2301/02; C08J 2489/00

(57) ABSTRACT

An electronic device element is described which is flexible, bendable or twistable without substantial degradation in optical or electrical properties. The electronic device element includes an optically transparent film constructed of a recombinant re-silin-CBD protein bound to cellulose nanocrystals (CNC). The recombinant resilin-CBD protein includes a Clostridium-derived cellulose-binding domain fused to resilin. The electronic device element may be a flexible display or flexible electronics element.

### FIELD OF THE INVENTION

The present invention related generally to films, particularly flexible, strong, and transparent films, for flexible displays and printable electronics and other applications, using cellulose nanocrystals (CNC) and Resilin-CBD (cellulose binding domain) recombinant protein.

### BACKGROUND OF THE INVENTION

In recent years, efforts to produce nanostructured, bioinspired composites have led to the development of nanoscale materials based on cellulosic raw material resources. Cellulose nanocrystals (CNC) are one of the most exciting new, wildly available biomaterials. CNC can be derived from cellulose, the main component of the cell wall of trees and plants, as well as plant-based human waste such as that of paper mills and municipal sewage system sludge. CNC is a highly crystalline form of nanostructured cellulose. The unique properties of nanocellulose include high Young's modulus and tensile strength (e.g., 150 GPa and 10 GPa for CNCs, nearly as strong as Kevlar and about 10 times stronger than steel), a range of aspect ratios that can be accessed depending on particle type, and potential compatibility with other materials, such as polymer, protein, and living cells.

Resilin is a protein with a nearly perfect elasticity. It is a member of the elastomer family, which includes protein such as collagen, elastin, spider-silks and foot mussel proteins. It is a rubber-like protein secreted by insects to specialized cuticle regions, where high resilience is required, usually for repetitive movements and high fatigue cycles. In terms of mechanical properties, resilin is a soft elastomer, displaying Young's modulus values of 50-300 kPa, and ultimate tensile strength of 60-300 kPa (depending on its source). Resilience is defined as the ability of a material to return to its original state following the removal of the applied stress. Resilin's outstanding resilience is >92%, and the crosslinked protein can be elongated up to three times its original length prior to break failure. Resilin is considered the most elastic material in nature.

### SUMMARY

The present invention seeks to provide compositions and methods for creating novel stiff yet flexible films. The films are bio-nanocomposite layers prepared by binding recombinant Resilin-CBD (RES-CBD) protein to cellulose nanocrystals (CNCs). In one aspect of the invention, the binding of RES-CBD to CNCs was 1:7 by mass, and the resulting res-CBD-CNCs films have shown enhanced mechanical properties.

In one aspect, the invention encompasses CNC and RES-CBD at different ratios and crosslinking methods or substances of CNC and/or its derivatives, and includes generating the films using different casting methods. CNC and/or derivatives crosslinking may be predominantly conducted with the components of CNC but may also bind to the protein (RES-CBD) in the film. Furthermore, various additional coating methods are developed, enabling effective peeling off the dried films.

These films may be used for flexible and printable electronics as they exhibit strong electrical resistance (that is, they can be an effective dielectric), while the addition of cross-linking generates water resistant properties.

### BRIEF DESCRIPTION OF THE DRAWINGS

The present invention will be better understood with reference to the following drawings and description. The components in the figures are not necessarily to scale, emphasis instead being placed upon illustrating the principles of the invention.

FIG. 1 is an illustration of a film of an embodiment of the invention (Res-CBD:CNC 1:7 ratio) cast on polyimide; the film displays ease of delamination from the substrate, transparency and flexibility.

FIG. 2 is a simplified schematic illustration of a reel-to-reel film of an embodiment of the invention.

FIG. 3 is a simplified graphical illustration of UV-Vis (ultraviolet-visible) measurements of optical films made in accordance with embodiments of the invention, wherein the tests were conducted on two repeats of CNC and RES-CBD:CNC films; samples containing RES:CBD at a concentration of 1:7 are the two highest curves and pure CNC films are the two lowest curves.

FIG. 4 is a simplified graphical illustration of a stress-strain curve for a film of Res-CBD:CNC ratio of 1:5 made in accordance with embodiments of the invention, wherein the calculated Young's Modulus was found to be E=7.9 GPa.

FIG. 5 is a simplified graphical illustration of a stress-strain curve for a film of Res-CBD:CNC ratio of 1:7 made in accordance with embodiments of the invention, wherein the calculated Young's Modulus was found to be E=13.8 GPa.

FIG. 6 is a simplified graphical illustration of a stress-strain curve for a film of Res-CBD:CNC ratio of 1:10 made in accordance with embodiments of the invention, wherein the calculated Young's Modulus was found to be E=11.9 GPa.

FIG. 7 is a simplified graphical illustration of a stress-strain curve for a film of Res-CBD:CNC ratio of 1:7 with addition of 0.5% Glycerol made in accordance with embodiments of the invention, wherein the calculated Young's Modulus was found to be E=7.3 GPa.

FIG. 8 is a simplified graphical illustration of a stress-strain curve for a film of Res-CBD:CNC ratio of 1:7 with addition of 5% Glycerol made in accordance with embodiments of the invention, wherein the calculated Young's Modulus was found to be E=9.5 GPa.

FIG. 9 is an illustration of prior art aluminum foil, a conductive material, which shows low electrical resistance.

FIG. 10 is an illustration of RES-CBD:CNC film made in accordance with embodiments of the invention, which is a dielectric material that shows high resistance (infinity).

FIG. 11, parts A, B, C, D, E, F, are illustrations of film, made in accordance with embodiments of the invention, before submerged in water:1:5, 1:7, 1:10, 1:7 +BL (1:10) with applied heat, 1:7+NF06, 1:7+BL (1:4), RES-CBD:CNC ratios, respectively; parts A1, B1, C1, D1, E1, F1 of FIG. 11 are illustrations of the film following 5 days in water (and after drying):1:5, 1:7, 1:10, 1:7+BL (1:10) with applied heat, 1:7+NF06, 1:7+BL (1:4), RES-CBD:CNC ratios, respectively.

### DETAILED DESCRIPTION

Carbohydrate Binding Modules (CBMs) are protein domains that mediate the binding of structural proteins to a variety of polysaccharide matrices and scaffolds. Two examples relevant to the present invention are the protein domains that enable the binding of chitin in the invertebrate kingdom and cellulose in the plant kingdom.

Clostridium cellulovorans produces a cellulase enzyme complex (cellulosome) containing a variety of cellulolytic subunits attached to a nonenzymatic scaffolding component termed CbpA. CbpA contains a family IIIa CBD, also referred as CBDclos, thus mediate the binding of the cellulosome to the cellulose surface. It has been proposed that family IIIa CBDs would bind to six consecutive glucose residues in a cellulose chain via its planar strip and anchoring residues (N21 and Q117). CBDclos cellulose binding is unique in the manner in which it maintains its specific cellulose binding properties under conditions in which most proteins are denatured and nonfunctional. Its binding is classified as irreversible, which is a characteristic of families II and III CBMs.

The first CBM that was cloned and displayed specific binding affinity to crystalline cellulose was the CBDclos.

In the present invention, a Clostridium-derived cellulose-binding domain, referred to as CBDclos, or for the sake of simplicity as CBD, is n-termini fused to resilin or a resilin-like protein (the term resilin encompassing both) to form recombinant Resilin-CBD. The CBD confer an intimate surface interaction, between stiff cellulose nanocrystals and a spring-like resilin, necessary for the assembly of novel biocomposite film that exhibit enhanced mechanical and physical properties. The recombinant resilin-CBD (RES-CBD) protein is bound to cellulose nanocrystals and formed into a film.

Accordingly, in the present invention, CNC and RES-CBD are combined to form optically transparent self-standing films. The optical transparency and good mechanical properties of the films make them highly relevant for flexible displays and other flexible electronics. Films may incorporate additives such as other materials, polymer, cross-linkers or surface modifications to impart desired properties such as hydrophobicity, flexibility, transparency, water resistance etc.

Furthermore, the natural self-assembly into chiral-nematic structures of CNC may influence the subsequent mechanical and optical properties of CNC based films. The introduction of various additives such as polymers and carbohydrates (glucose) may influence the self-assembly behavior and the ensuing nanostructure of the film, resulting in further enhanced transparency and desired mechanical properties.

One of the many applications of the present invention is using the film as a flexible display. A flexible display is a visual output surface that is designed to withstand being folded and/or bent and/or twisted. Typically screens which use flexible displays are made of OLED (organic light emitting diode) displays. Flexible displays are becoming more prevalent in foldable technology such as in foldable smartphones, designed to be folded or closed like a book, roll-up screens or wearable devices. The film of the present invention can be used to make ultra-thin displays without the fragility of glass screens.

In the prior art, a flexible OLED is based on a flexible substrate which can be either plastic (most common is polyimide film), metal or flexible glass. One of the things that happens with an OLED screen is that the pixels, the light portion of the screen that emits light or that displays an image, is actually built into the screen itself. Accordingly, the LEDs are on the actual screen substrate instead of being behind it and projecting through a glass panel. In contrast, the invention offers a new solution for such a substrate that is flexible, transparent, dielectric and strong, based on RES-CBD:CNC film. Flexible electronics is another application of the invention. RES-CBD:CNC films of the invention create a thin layer on which are mounted or printed electronic components and which can be further bent and shaped in different ways for different uses. Taking advantage of the ability to use these bio-based materials, electronic capability can then be incorporated into more consumer and industrial products, bringing digital “green” intelligence to the greater world. These flexible electronics will eventually result in higher volume at lower costs.

### EXEMPLARY MATERIALS AND METHODS

### Example 1

### Casting and Drying—Methods and Substrates Casting

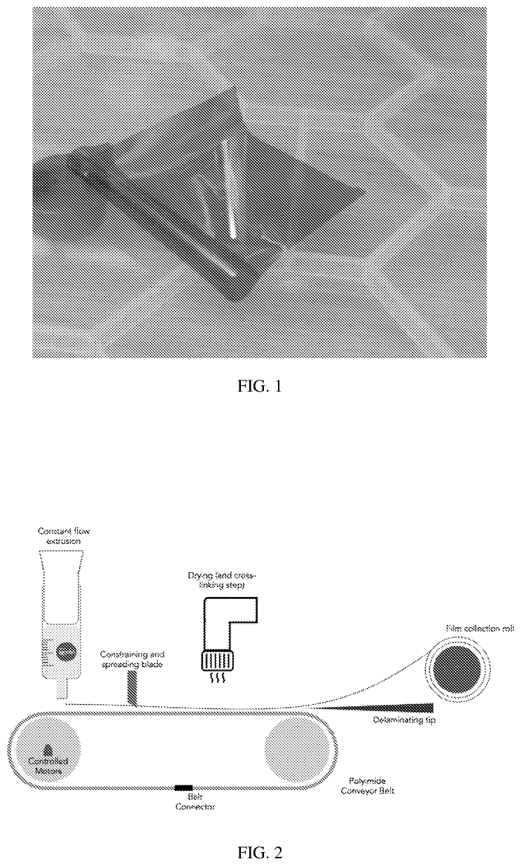

Res-CBD:CNC mixture is casted in its viscous form and dried to solidify as a film (FIG. 1). Multiple methods have been explored for the fabrication route. Films can be drop-casted on various substrates and let to dry.

Drop casting has been made in various forms including using pipette tips and drop casting in a define patterns that influence orientation of CNC crystals and resilin protein. To obtain random orientation for maximal isotropic behavior, a drop casting in a labyrinth pattern was performed.

To enforce a control on thickness, an RK K control coater has been used with a variety of thread for varying final thickness of wet produce on substrate.

In a reel-to-reel process (FIG. 2), continuous extrusion on a moving conveyor belt may be homogenized with the help of a controlled height blade.

### Drying

Drying may be performed in a clean room to avoid impurities during drying process, later acting as defects affecting mechanical and/or optical behavior.

Hot air flow on drying may be controlled to allow homogenous surface profile and constant thickness. Stress applied on the surface due to blow gun can be later relieved in annealing post-processing steps.

Drying time for a 5 by 7 cm film in a closed environment is approx. 12 hours.

### Substrates

Films have been cast on glass, polystyrene and polyimide surfaces. Adhesion to surface was found to go from stronger to weaker from glass, polystyrene to polyimide.

Glass was treated with SIGMACOTE as a siliconizing agent to reduce post-drying adhesion. Films as a result peel-off better but visible residues of the agent are present on an inferior surface of the film.

Edged substrates provided control on final size and dry weight but introduce stress concentrators and sources of fracture during peel-off step. Additional possible coating: hydrophobic, such as: Teflon, negatively such as: SDS (Sodium dodecyl sulfate) and SLS (Sodium lauryl sulfate).

### Example 2

### Optical Measurements

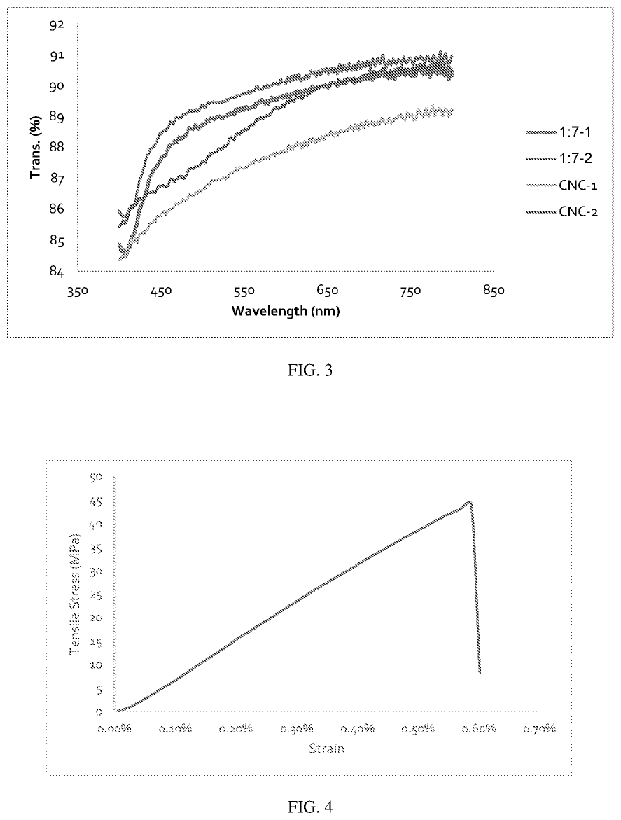

A set of four films were cast. A pure CNC film was used as a control compared to 1:7 RES-CBD:CNC ratio in order to obtain optical properties such as total transmittance (TT). Freeze-dried RES-CBD was dissolved in CNC suspensions at a 1:7 and 1:0 w/w RES-CBD:CNC ratios. A series of films were cast from RES-CBD:CNC suspensions (20 mL suspension volume per film). Prior to film casting, the mixtures were gently rotated at room temperature for 1 h to allow the binding of the CBD domain to the crystalline nanocellulose. The films were prepared by solution casting onto polystyrene substrates, and slowly dried in ambient conditions until constant weight was achieved. Total transmittance was evaluated by using a UV-Vis apparatus (JASCO Corp., V-570, Weizmann institute, Israel), scanning at a range of 400-800 nm. All samples exhibited good transmittance capabilities (˜90%), slightly faltering at the lower ends of the spectrum (FIG. 3). Samples containing RES:CBD (the two highest curves) exhibited better results, keeping a TT of 90% on most of the visible spectrum. CNC films (the two lowest curves) show slightly decreased TT, specifically in the lower range of the visible-light spectrum (>600 nm).

### Example 3

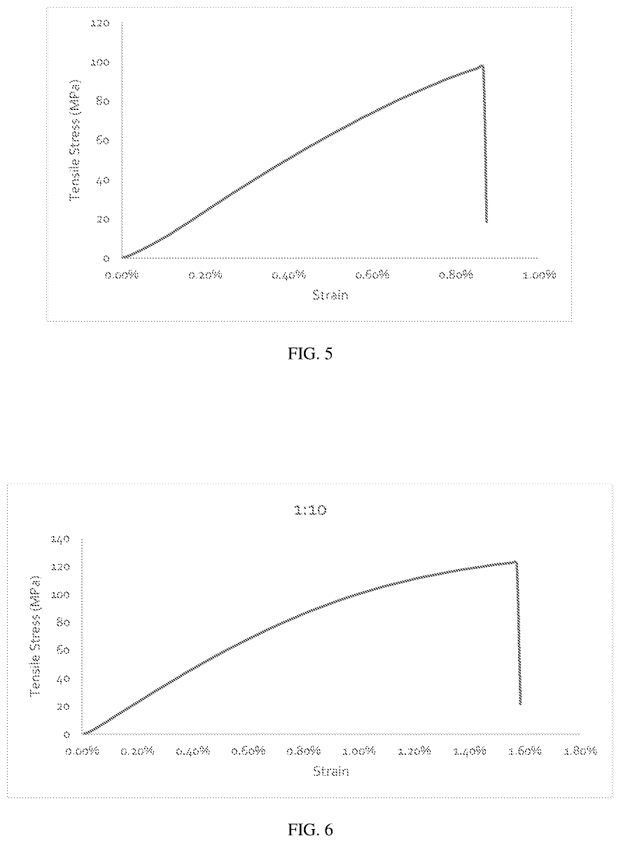

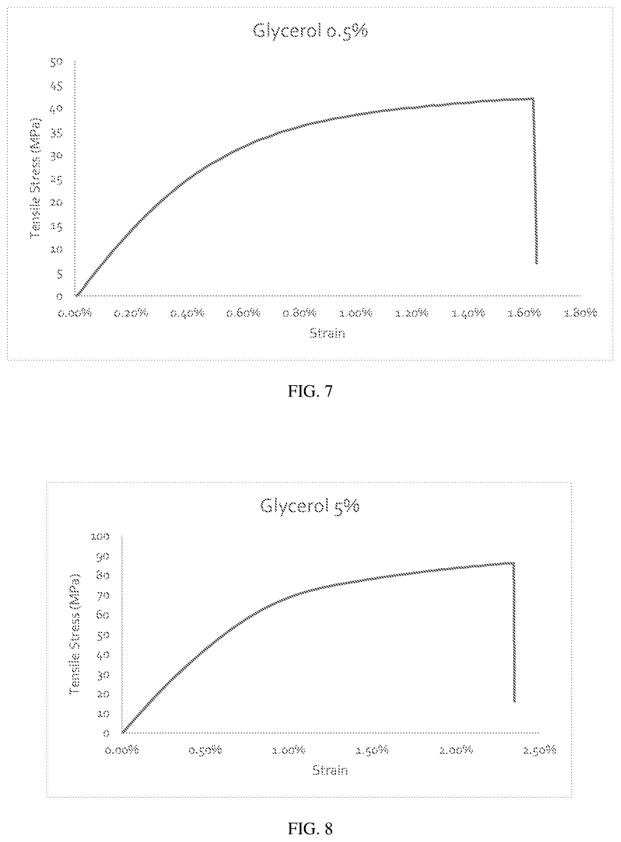

### Mechanical Properties (FIGS. 4-8)

All films were tested under Tensile stress conditions on an Instron system (Instron 3345 Tester, Instron, Norwood, Mass.).

The influence of casting conditions and Res-CBD to CNC ratios were investigated. Ratios of 1:5, 1:7 and 1:10 yielded Young's Moduli of 7.9, 13.8, 11.9 GPa respectively. This result justifies the choice of the 1:7 Res-CBD : CNC ratio as optimum.

The addition of Glycerol in concentrations of 0.5% and 5% generated Young's Moduli of 7.3 and 9.5 GPa respectively.

Samples were cut with surgical blades to rectangular dimensions of 3 to 7 mm in width, 10 to 25 mm in length and 25 to 50 microns in thickness.

Addition of glycerol lowers Young's Modulus but increases the plastic tensile strain before fracture of films.

Films were kept in sealed containers and were taken out for tensile testing in room temperature of 22° C. and 60% humidity on average.

It is preferred to use constant cutting method such as laser cutting. In addition, it is preferred to use controlled air flow and temperature for drying to ensure homogenous surface profile

### Example 4

### Electrical Characteristics

The inventors have characterized the dielectric properties of the RES-CBD:CNC films (1:5, 1:7, 1:10 ratios and crosslinked films).

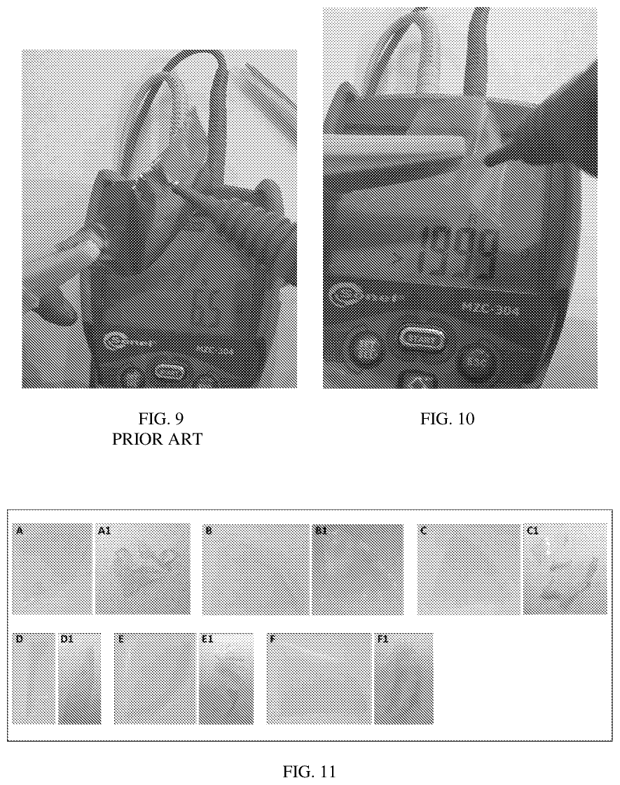

The use of cellulose and resilin protein as a reliable electrically insulating composite material is justified by the combination of its dielectric and mechanical properties such as high resistivity (>1999 Ω, (infinity)) (FIG. 10), high strength (modulus>11 GPa), chemical stability, flexibility, availability as biodegradable materials and low cost. Aluminum foil was used a control for conductive material with low resistivity of 6.5 Ω (FIG. 9).

Resistance measurements were preformed using Sonel Insulation Resistance Meter MZC-304.

### Example 5

### Water Durability Tests (FIG. 11)

A set of six films was cast. A 1:5, 1:7 and 1:10 RES-CBD:CNC films, three films in a 1:7 ratio and with the addition of crosslinkers: BL and nf06 (both are blocked isocyanate). BL refers to BAYHYDUR BL 5335, supplied by Covestro LLC while nf06 refers to Hydrosin NF-06 supplied by Maflon, Italy. Crosslinker ratio were: 1:4 (BL), 1:10 (BL)+heat treatment at 80° C. and 1:40 (nf06). All samples were photographed and submerged in 4 mL DDW for 5 days in order to assert water durability (force to tear) and resistance (degradation while submerged in water). After 5 days in water all samples showed no sign of degradation, keeping completely intact. However, following drying, only two samples stayed intact, ratio of 1:7 and ratio of 1:7 with the addition of crosslinker (1:10 BL+80° C. heat treatment). The 1:7 film became murky, while in the presence of the crosslinker the film remained similar to the origin. This suggests that the films durability in ambient humidity is best when adding cross-linker in the appropriate ratios and suitable conditions.

What is claimed is:

1. An article comprising:
an electronic device element which is flexible, bendable or twistable without substantial degradation in optical or electrical properties, said element comprising an optically transparent film constructed of a recombinant resilin-CBD protein bound to cellulose nanocrystals (CNC), said recombinant resilin-CBD protein comprising a Clostridium-derived cellulose-binding domain fused to resilin.

2. The article according to claim 1, wherein said electronic device element comprises a display.

3. The article according to claim 1, wherein said electronic device element is part of a foldable phone.

4. The article according to claim 1, wherein said electronic device element comprises a roll-up display screen.

5. The article according to claim 1, wherein said electronic device element is part of a wearable device.

6. The article according to claim 1, wherein said film comprises electronic components mounted thereon.

7. The article according to claim 1, wherein said film comprises electronic components printed thereon.

8. The article according to claim 1, wherein said film further comprises a carbohydrate.
